(19) United States
(12) Patent Application Publication
(10) Pub. No.: US 2005/0063159 A1
(43) Pub. Date: Mar. 24, 2005

(54) Heat-dissipating fin module

(76) Inventor: Richard Ma, Taipei (TW)

Correspondence Address: BIRCH STEWART KOLASCH & BIRCH, PO BOX 747, FALLS CHURCH, VA, 22040-0747, US

(21) Appl. No.: 10/667,369

(22) Filed: Sep. 23, 2003

(51) Int. Cl. H05K 7/20

(52) U.S. Cl. 361/704

(57) ABSTRACT

A heat-dissipating fin module installed on a heat-generating component of an electronic device for help dissipating heat generated thereby. The heat-dissipating fin module has a heat-conductive substrate in direct contact with the heat-generating component for transferring heat. Through the installation of several first fins and several second fins with curved surfaces and curvature centers on opposite sides, both the heat-conductive area and the heat conducting time are increased. A curved airflow path is formed to provide good convective heat dissipation.

### BACKGROUND OF THE INVENTION

1. Field of Invention

The invention relates to a heat-dissipating fin module for heat-generating devices. In particular, it is a heat-dissipating fin module for side-blowing fans.

2. Related Art

An electronic device is comprised of many electronic elements. Taking the computer as an example, there are many electronic elements on the motherboard that can generate a lot of heat during operations. Such elements include the central processing unit (CPU), the south/north bridge chips, the graphics chip, and the dual in-line memory modules (DIMM's). The operation speeds of these electronic elements become much faster than before. For example, the work frequency of the CPU is now over 1 GHz, with a heat-dissipating power of 50 W. If the heat cannot be immediately removed, these electronic elements may be overheated to affect their stability and reliability and to shorten their lifetime. Therefore, heat dissipation is a serious problem when the electronic device operation frequencies become higher.

Currently, the electronic device heat dissipation is achieved by heat conduction, convection or radiation to release the generated heat to the environment. A primary means is to use the combination of a heat-dissipating fin module and a fan. The heat-dissipating fin module is made of metal. It has a heat-conductive base whose bottom is directly installed on the electronic device that generates heat. The heat-conductive base is formed with several heat-dissipating fins. The heat produced by the heat-generating electronic device is transferred via the heat-conductive base to the heat-dissipating fins. The fan generates airflow through the fins to have heat exchange with the fins. The heated air is then expelled to the ambient space, bringing away the heat on the heat-dissipating fin module and lowering the temperature of the electronic device.

The heat-dissipation efficiency of the fin module is usually determined by its material and structure. The early heat-dissipating fin modules are often made of aluminum because of its small thermal resistance, light weight and low cost. However, as the electronic device work frequency continuously increases, the heat-dissipation efficiency has to be increased too. Therefore, people start to use copper as the material for heat-dissipating modules.

The thermal conduction coefficient of copper is about 1.8 times that of aluminum, while the density of copper is about 3 times that of aluminum. In other words, for heat-dissipating fin modules of the same volume and area, the one made of copper is 3 times heavier than that made of aluminum. Therefore, although the heat-dissipating fin module made of copper has a better thermal conduction coefficient than that made of aluminum; the former is much heavier than the latter. One thus has to take both the weight and the thermal conduction coefficient factors into account when making the fins.

Existing heat-dissipating fin modules on the market are all made of materials with similar compositions. The heat-dissipation efficiencies are also very close. Therefore, how to increase heat dissipation by having a better structure has become the main research goal of the manufacturers.

For example, the heat-dissipating fins are usually installed vertically on the base of a heat-dissipating fin module. One of the features of a vertical heat-dissipating fin module is that the flat fins provide linear airflow channels. However, the drawbacks of this structure are that the heat-conductive area is too small, that the heat transfer time is too short, and that the parallel airflow cannot provide ideal heat convection once leaving the separation of the fins. Although the patent provides a layered structure, the structure and arrangement of the vertical structure still have room for improvement.

### SUMMARY OF THE INVENTION

In view of the foregoing, the invention wants to solve the problems for vertical heat-dissipating fin that the heat conduction area is small, that the heat transfer time is short, and that the linear airflow channel cannot provide ideal heat convection effects.

In view of the foregoing, the disclosed heat-dissipating fin module includes: a heat-conductive base installed on a heat-generating component of an electronic device; several first heat-dissipating fins vertically installed at intervals on one half side of the heat-conductive base; several second heat-dissipating fins vertically installed at intervals on the other half side of the heat-conductive base. Each of the first heat-dissipating fins has a curved surface and is parallel to one another. The space between adjacent first heat-dissipating fins forms a first airflow space for air to pass through. Each of the second heat-dissipating fins has a curved surface and is parallel to one another. However, the curvature centers of the second heat-dissipating fins are on the opposite side to those of the first heat-dissipating fins. The space between adjacent second heat-dissipating fins forms a second airflow space for air to pass through.

The invention achieves through the curved first heat-dissipating fins and second heat-dissipating fins the effects that the heat-conductive area is increased, that the heat transfer time is elongated, and that the curved airflow paths provide ideal heat convection effects.

### BRIEF DESCRIPTION OF THE DRAWINGS

The invention will become more fully understood from the detailed description given hereinbelow illustration only, and thus are not limitative of the present invention, and wherein:

FIG. 1 is a three-dimensional view of a preferred embodiment of the invention; and

FIG. 2 is a schematic top view of FIG. 1.

### DETAILED DESCRIPTION OF THE INVENTION

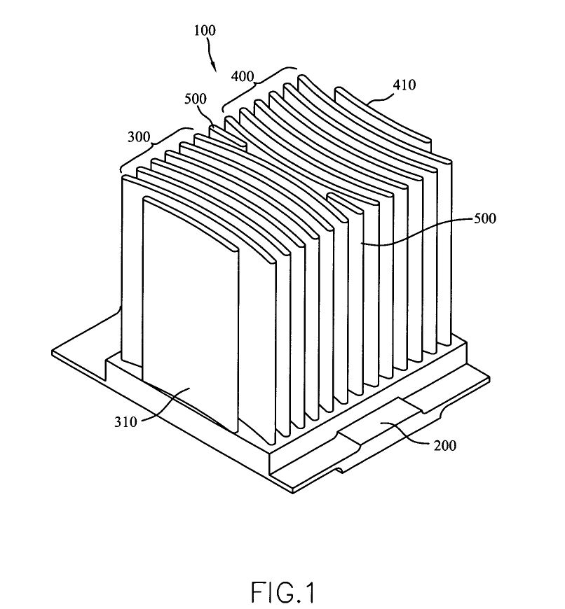

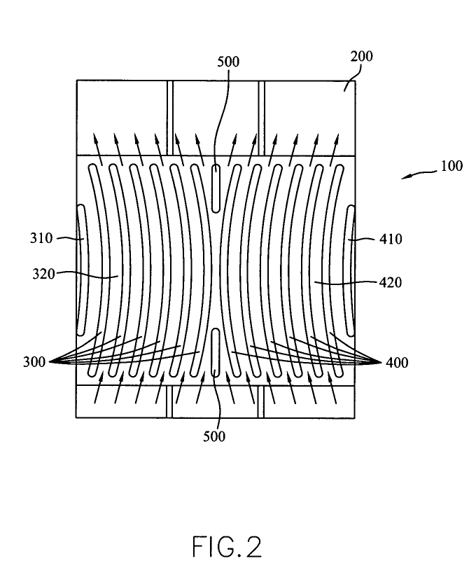

With reference to FIGS. 1 and 2, the heat-dissipating fin module 100 according to a preferred embodiment of the invention can be applied to heat-generating devices such as the CPU, the south/north bridge chips, the graphics chip, and the DIMM's, avoiding the devices from damages due to overheating. The heat-dissipating fin module 100 is made of metals with high thermal conduction coefficients (e.g. aluminum and copper). It consists of a heat-conductive base 200, several first heat-dissipating fins 300, several second heat-dissipating fins 400, and two third heat-dissipating fins 500.

The heat-conductive base 200 is a piece of block that fits that shape of the heat-generating device. Its bottom is attached to the heat-generating device (not shown) for direct contact. Generally speaking, a heat-dissipating gel is applied between the heat-conductive base 200 and the heat-generating device. This increases the thermal conductance of the system.

The first heat-dissipating fins 300 are vertically installed on the front half side of the heat-conductive base 200 (referring to FIG. 1). Each of the first heat-dissipating fins 300 has an arc shape. They are installed by gluing or welding. They can also be formed by cutting or squeezing. All the first heat-dissipating fins 300 are parallel and equal in length. The centers of the curved surfaces are on a line. The space between adjacent first heat-dissipating fins 300 is a first airflow space 320, forming a curved airflow path. Moreover, the outermost first heat-dissipating fin 310 is shorter for fitting the rectangular shape of the heat-conductive base 200.

The second heat-dissipating fins 400 are also installed vertically on the rear half side of the heat-conductive base 200 (see FIG. 1). Each of the second heat-dissipating fins 400 has an arc shape. They are installed by gluing or welding. They can also be formed by cutting or squeezing. Although the centers of the second heat-dissipating fins 400 are also on the same line as those of the first heat-dissipating fins 300, they are on opposite sides. All the second heat-dissipating fins 400 are parallel and equal in length. The space between adjacent first heat-dissipating fins 400 is a first airflow space 420, forming a curved airflow path. Similarly, the outermost first heat-dissipating fin 410 is also shorter for fitting the rectangular shape of the heat-conductive base 200.

The third heat-dissipating fins 500 are also installed vertically on the heat-conductive base 200. They are on the outer sides of the neighboring area between the first heat-dissipating fins 300 and the second heat-dissipating fins 400. The purpose of having these two third heat-dissipating fins 500 is to fully utilize the space, increasing the heat-dissipation area. They are straight without bending to either side. Of course, it does not matter if the two third heat-dissipating fins are installed.

After installing the disclosed heat-dissipating fin module 100 on a heat-generating device, a fan is provided on one side (not shown) to produce airflow. The airflow paths are shown in FIG. 2. Since both the first heat-dissipating fins 300 and the second heat-dissipating fins 400 have curved surfaces, there is a larger heat-dissipation area and the curved airflow paths have a longer length for elongating the heat transfer time. As the airflow paths on both sides do not cross or overlap, a better heat convection effect is achieved.

Certain variations would be apparent to those skilled in the art, which variations are considered within the spirit and scope of the claimed invention.

1. A heat-dissipating fin module comprising:
a heat-conductive base, which is installed on a heat-generating component of an electronic device;
a plurality of first heat-dissipating fins, which are vertically installed at intervals on one half side of the heat-conductive base, each of the first heat-dissipating fins having an arc surface parallel to one another, and the space between adjacent first heat-dissipating fins forming a first airflow space for providing a curved airflow path; and
a plurality of second heat-dissipating fins, which are vertically installed at intervals on the other half side of the heat-conductive base, each of the second heat-dissipating fins having an arc surface parallel to one another but having curvature centers opposite to those of the first heat-dissipating fins, and the space between adjacent second heat-dissipating fins forming a second airflow space for providing a curved airflow path that does not cross the airflow path of the first airflow space.

2. The heat-dissipating fin module of claim 1, wherein the first heat-dissipating fins and the second heat-dissipating fins are equal in length.

3. The heat-dissipating fin module of claim 1, wherein the curvature centers of the first heat-dissipating fins and the second heat-dissipating fins are on the same line.

4. The heat-dissipating fin module of claim 1, wherein the outermost first heat-dissipating fin and second heat-dissipating fin are shorter.

5. The heat-dissipating fin module of claim 1, wherein the first heat-dissipating fins and the second heat-dissipating fins are installed on the heat-conductive base by a method selected from gluing and welding.

6. The heat-dissipating fin module of claim 1, wherein the first heat-dissipating fins and the second heat-dissipating fins are formed on the heat-conductive base by cutting and squeezing.

7. The heat-dissipating fin module of claim 1, wherein the first heat-dissipating fins and the second heat-dissipating fins have trimmed sides.

8. The heat-dissipating fin module of claim 1 further comprising at least one third heat-dissipating fin installed vertically in the outer region between the first heat-dissipating fins and the second heat-dissipating fins on the heat-conductive base.

9. The heat-dissipating fin module of claim 8, wherein the third heat-dissipating fin is straight.

10. The heat-dissipating fin module of claim 8, wherein the third heat-dissipating fin is installed by a method selected from gluing and welding.

11. The heat-dissipating fin module of claim 8, wherein the third heat-dissipating fin is formed by cutting and squeezing.

12. A heat-dissipating fin module comprising:
a heat-conductive base, which is installed on a heat-generating component of an electronic device;
a plurality of first heat-dissipating fins, which are vertically installed at intervals on one half side of the heat-conductive base, each of the first heat-dissipating fins having an arc surface parallel to one another, and the space between adjacent first heat-dissipating fins forming a first airflow space for providing a curved airflow path;
a plurality of second heat-dissipating fins, which are vertically installed at intervals on the other half side of the heat-conductive base, each of the second heat-dissipating fins having an arc surface parallel to one another but having curvature centers opposite to those of the first heat-dissipating fins, and the space between adjacent second heat-dissipating fins forming a second airflow space for providing a curved airflow path that does not cross the airflow path of the first airflow space; and
at least one third heat-dissipating fin, which is vertically installed on the heat-conductive base in an outer region between the first heat-dissipating fins and the second heat-dissipating fins.

13. The heat-dissipating fin module of claim 12, wherein the first heat-dissipating fins and the second heat-dissipating fins are equal in length.

14. The heat-dissipating fin module of claim 12, wherein the curvature centers of the first heat-dissipating fins and the second heat-dissipating fins are on the same line.

15. The heat-dissipating fin module of claim 12, wherein the outermost first heat-dissipating fin and second heat-dissipating fin are shorter.

16. The heat-dissipating fin module of claim 12, wherein the third heat-dissipating fin is straight.

17. The heat-dissipating fin module of claim 12, wherein the first heat-dissipating fins, the second heat-dissipating fins, and the third heat-dissipating fins are installed on the heat-conductive base by a method selected from gluing and welding.

18. The heat-dissipating fin module of claim 12, wherein the first heat-dissipating fins, the second heat-dissipating fins, and the third heat-dissipating fins are formed on the heat-conductive base by cutting and squeezing.
